(19) United States
(12) Patent Application Publication
(10) Pub. No.: US 2025/0359400 A1
(43) Pub. Date: Nov. 20, 2025

(54) LIGHT-EMITTING ELEMENT AND DISPLAY DEVICE AND LIGHTING DEVICE INCLUDING THE LIGHT-EMITTING ELEMENT

(71) Applicant: Japan Display Inc., Tokyo (JP)

(72) Inventors: Masumi NISHIMURA, Tokyo (JP); Hayata AOKI, Tokyo (JP)

(73) Assignee: Japan Display Inc., Tokyo (JP)

(21) Appl. No.: 19/281,954

(22) Filed: Jul. 28, 2025

Related U.S. Application Data
(63) Continuation of application No. PCT/JP2024/003827, filed on Feb. 6, 2024.

(30) Foreign Application Priority Data
Mar. 2, 2023 (JP) 2023-031815

(51) Int. Cl. H10H 20/825; H10H 20/854; H10H 20/855

(52) U.S. Cl. CPC H10H 20/825; H10H 20/854; H10H 20/855

(57) ABSTRACT

A light-emitting element includes a substrate, an electroluminescent laminate over the substrate, an anode and a cathode electrically connected to the electroluminescent laminate, and a plurality of optical adjustment films over the electroluminescent laminate. The electroluminescent laminate includes a plurality of functional layers containing a gallium nitride-based material. The plurality of optical adjustment films is configured so that refractive indices decrease with increasing distance from the electroluminescent laminate. The plurality of optical adjustment films may independently contain a material selected from aluminum nitride, silicon nitride, silicon oxide, titanium oxide, zirconium oxide, chromium oxide, aluminum oxide, indium oxide, lead sulfide, and a polymer containing sulfur, halogen, or phosphorus.

### CROSS-REFERENCE TO RELATED APPLICATIONS

This application is a Continuation of International Patent Application No. PCT/JP2024/003827, filed on Feb. 6, 2024, which claims the benefit of priority to Japanese Patent Application No. 2023-031815, filed on Mar. 2, 2023, the entire contents of which are incorporated herein by reference.

### FIELD

An embodiment of the present invention relates to a light-emitting element and a display device and a lighting device including the light-emitting element. For example, an embodiment of the present invention relates to a highly efficient light-emitting element including an inorganic semiconductor and a display device and a lighting device including the light-emitting element.

### BACKGROUND

In recent years, light-emitting elements containing an inorganic semiconductor (hereinafter, simply referred to as LEDs) have been used in a variety of lighting devices and display devices. Since LEDs are capable of emitting light at high luminance and have a long lifetime, the use of the LEDs allows the production of highly reliable display devices and lighting devices with reduced power consumption. For example, International Patent Publication No. 2018/042792 and Japanese Laid-Open Patent Publication No. 6723484 disclose that LEDs can be fabricated over amorphous glass substrates.

### SUMMARY

An embodiment of the present invention is a light-emitting element. The light-emitting element includes a substrate, an electroluminescent laminate over the substrate, an anode and a cathode electrically connected to the electroluminescent laminate, and a plurality of optical adjustment films over the electroluminescent laminate. The electroluminescent laminate includes a plurality of functional layers containing a gallium nitride-based material. The plurality of optical adjustment films is configured so that refractive indices decrease with increasing distance from the electroluminescent laminate.

An embodiment of the present invention is a light-emitting element. The light-emitting element includes a substrate, a plurality of optical adjustment films over the substrate, an electroluminescent laminate over the plurality of optical adjustment films, and an anode and a cathode electrically connected to the electroluminescent laminate. The electroluminescent laminate includes a plurality of functional layers containing a gallium nitride-based material. The plurality of optical adjustment films is configured so that refractive indices decrease with increasing distance from the electroluminescent laminate.

An embodiment of the present invention is a display device or a lighting device comprising the aforementioned light-emitting element.

### BRIEF DESCRIPTION OF DRAWINGS

FIG. 1 is a schematic top view of a display device according to an embodiment of the present invention.

FIG. 2A is a schematic cross-sectional view of a light-emitting element according to an embodiment of the present invention.

FIG. 2B is a schematic cross-sectional view of a light-emitting element according to an embodiment of the present invention.

FIG. 2C is a schematic cross-sectional view of a light-emitting element according to an embodiment of the present invention.

FIG. 3A is a schematic cross-sectional view of a light-emitting element according to an embodiment of the present invention.

FIG. 3B is a schematic cross-sectional view of a light-emitting element according to an embodiment of the present invention.

FIG. 3C is a schematic cross-sectional view of a light-emitting element according to an embodiment of the present invention.

FIG. 4A is a schematic cross-sectional view of a light-emitting element according to an embodiment of the present invention.

FIG. 4B is a schematic cross-sectional view of a light-emitting element according to an embodiment of the present invention.

FIG. 4C is a schematic cross-sectional view of a light-emitting element according to an embodiment of the present invention.

FIG. 5A is a schematic cross-sectional view of a light-emitting element according to an embodiment of the present invention.

FIG. 5B is a schematic cross-sectional view of a light-emitting element according to an embodiment of the present invention.

FIG. 5C is a schematic cross-sectional view of a light-emitting element according to an embodiment of the present invention.

FIG. 6 is a schematic top view of a lighting device according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

### First Embodiment

In the present embodiment, an LED according to an embodiment of the present invention and a display device including the LED are explained.

### 1. Display Device

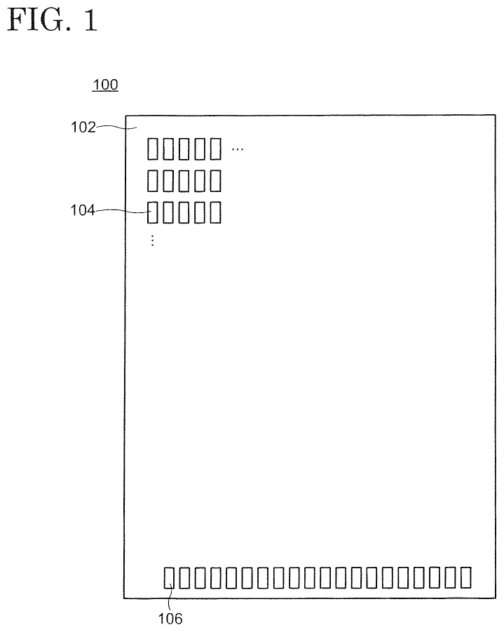

FIG. 1 shows a schematic top view of the display device 100. As shown in FIG. 1, the display device 100 has a substrate 102 over which a plurality of pixels 104 is provided in a matrix shape. As described in detail below, one or a plurality of LEDs is arranged in each pixel 104. The smallest region encompassing all of the pixels 104 and a region surrounding this region are respectively defined as a display region and a peripheral region. A plurality of terminals 106 is provided along one edge of the substrate 102 in the peripheral region, and a variety of signals and power supplies for images are supplied through the terminals 106 from an external circuit which is not illustrated. Although a detailed explanation is omitted, a pixel circuit composed of one or a plurality of transistors and one or a plurality of capacitance elements may be provided in each pixel 104, and each pixel 104 may be controlled using the pixel circuit. This configuration allows images to be displayed in the display region.

### 2. Light-Emitting Element (LED)

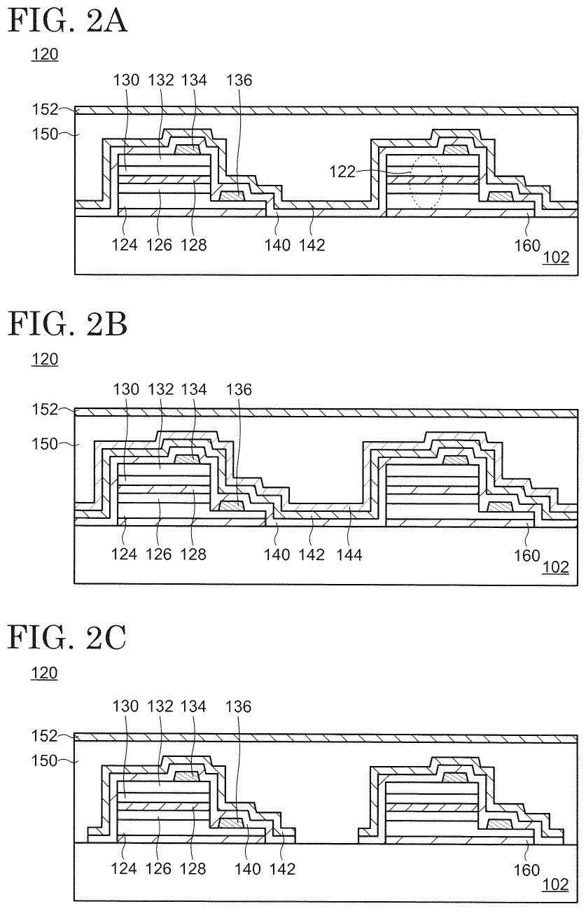

A schematic cross-sectional view of two adjacent LEDs 120 is shown in FIG. 2A. Each LED 120 has an electroluminescent laminate 122 and an anode 134 and a cathode 136 electrically connected to the electroluminescent laminate 122 over the substrate 102. The LED 120 further includes a plurality of optical adjustment films (e.g., first optical adjustment film 140 and second optical adjustment film 142) covering the electroluminescent laminate 122.

### (1) Substrate

As described below, the electroluminescent laminate 122 of the LED 120 is formed using a sputtering method. Therefore, the substrate 102 is not required to have the resistance to high temperatures required for epitaxial growth of inorganic semiconductors and may have a heat resistance to a temperature of approximately 400° C., for example. Specifically, an amorphous glass substrate may be used as the substrate 102 in addition to a single crystal silicon substrate, a sapphire substrate, and a quartz substrate. Alternatively, a resin substrate such as a polyimide substrate, a polyamide substrate, a polycarbonate substrate, an acrylic resin substrate, a polysiloxane substrate, or a fluorine-based resin substrate may be used as the substrate 102. The substrate 102 may be flexible. Therefore, a large glass substrate, also called mother glass, may be used as the substrate 102. Preferably, a substrate with a low coefficient of thermal expansion, a high strain point, and a high surface flatness is used as the substrate 102. For example, the substrate 102 is preferred to have a coefficient of thermal expansion lower than 50×10⁻⁷/° C. and a strain point equal to or higher than 600° C. Moreover, the content of alkali metals such as sodium in the substrate 102 is preferred to be equal to or less than 0.1%. Hence, when the substrate 102 is an amorphous glass substrate, a glass substrate formed of aluminoborosilicate glass or aluminosilicate glass may be used, for example. Although not illustrated, an undercoat may be provided over the substrate 102 to prevent the diffusion of impurities such as alkali metal ions. The undercoat is formed, for example, by a sputtering method or a chemical vapor deposition (CVD) method and is a single film or a laminate of a plurality of films containing a silicon-containing inorganic compound such as silicon oxide and silicon nitride.

### (2) Electroluminescent Laminate

The electroluminescent laminate 122 is configured to emit visible light when holes and electrons respectively injected from the anode 134 and the cathode 136 are recombined. The electroluminescent laminate 122 is composed of a stack of a plurality of functional layers. There are no restrictions on the number and the functions of the functional layers included in each electroluminescent laminate 122, and the functional layers may include, for example, an electron-injection layer 124, an electron-transporting layer 126, an emission layer 128, a hole-transporting layer 130, and a hole-injection layer 132. These functional layers may each have a single-layer structure or a stacked-layer structure in which a plurality of layers is stacked. Although an explanation is provided below using, as an example, the electroluminescent laminate 122 in which the electron-injection layer 124, the electron-transporting layer 126, the emission layer 128, the hole-transporting layer 130, and the hole-injection layer 132 are stacked in order from the substrate 102 side, there is no restriction on the stacking order of these functional layers, and the electroluminescent laminate 122 may be constructed in the reverse stacking order of the above order.

Each functional layer contains an inorganic semiconductor, and a compound including a Group 13 element and a Group 15 element is represented as the inorganic semiconductor. More specifically, semiconductors containing aluminum, gallium, and/or indium as well as nitrogen, phosphorus, and/or arsenic are represented. Typically, gallium-based materials are represented. For example, gallium nitride-based materials such as gallium nitride (GaN), aluminum gallium nitride (AlGaN), and indium gallium nitride (InGaN), gallium phosphide-based materials such as gallium phosphide (GaP) and aluminum indium gallium phosphide (AlGaInP), and the like are represented. A dopant may be included in each functional layer. An element such as silicon, germanium, magnesium, zinc, cadmium, and beryllium is represented as a dopant. The addition of these elements enables valence electron control of each functional layer, thereby not only maintaining the intrinsic (i-type) property but also enabling band gap control and imparting p-type conductivity and n-type conductivity.

A functional layer imparted with p-type conductivity is used as the hole-transporting layer 130 and the hole-injection layer 132, while a functional layer imparted with n-type conductivity is used as the electron-injection layer 124 and the electron-transporting layer 126. For example, the electron-injection layer 124, the electron-transporting layer 126, the hole-transporting layer 130, and the hole-injection layer 132 may be respectively configured to include n-type gallium nitride, n-type aluminum gallium nitride, p-type aluminum gallium nitride, and p-type gallium nitride.

The emission layer 128 may be a single-layer structure of indium gallium nitride or may have a quantum well structure, for example. A quantum well structure is a structure in which a plurality of thin films having different band gaps and thicknesses from approximately 1 nm to 5 nm is alternately stacked. For example, alternating layers of indium gallium nitride and gallium nitride, alternating layers of indium gallium arsenide phosphide (GaInAsP) and indium phosphide (InP), alternating layers of indium aluminum arsenide (AlInAs) and indium gallium arsenide (InGaAs), and the like are exemplified.

Each functional layer included in the electroluminescent laminate 122 may be formed using a sputtering method. For example, the substrate 102 and a gallium nitride target are placed in a chamber of a sputtering apparatus. An atomic ratio of gallium to nitrogen in the gallium nitride target is preferred to be equal to or more than 0.7 and equal to or less than 2. After exhausting the chamber sufficiently, a sputtering gas is supplied. Examples of a sputtering gas include rare gases such as argon and krypton. The substrate 102 is heated at a temperature from room temperature to a temperature less than 600° C., preferably at a temperature equal to or higher than 100° C. and equal to or lower than 400° C. Thus, the substrate 102 containing amorphous glass can be used. Furthermore, a voltage is applied between the substrate 102 and the gallium nitride target to generate plasma, by which the sputtering gas is ionized. The ionized sputtering gas is accelerated to impinge on the target, and the deposition material scattered by this impact is deposited over the substrate 102, resulting in the functional layer containing gallium nitride. When a gallium nitride target containing silicon or a gallium nitride target containing magnesium is used instead of the gallium nitride target, the functional layers imparted with n-type or p-type conductivity can be fabricated. In addition, it is possible to deposit stacked films in which indium gallium nitride films and gallium nitride films are alternately stacked by using an indium gallium nitride target and a gallium nitride target.

### (3) Anode and Cathode

The anode 134 and the cathode 136 are electrically connected to the functional layers exhibiting p-type conductivity (the hole-injection layer 132 or the hole-transporting layer 130) and n-type conductivity (the electron-injection layer 124 or the electron-transporting layer 126), respectively. As the anode 134, a thin film of a metal such as palladium and gold or an alloy of these metals can be used, for example. As the cathode 136, a metal such as silver and indium or an alloy of these metals can be used. The LED 120 according to the present embodiment is configured so that the light emission obtained in the emission layer 128 is extracted on the anode 134 side. Therefore, the anode 134 is provided so as not to entirely cover the hole-injection layer 132 or the hole-transporting layer 130. In other words, the hole-injection layer 132 or the hole-transporting layer 130 in contact with the anode 134 is at least partially exposed from the anode 134. Although both the anode 134 and the cathode 136 are disposed over the functional layers in the LEDs 120 demonstrated in FIG. 2A, either the anode 134 or the cathode 136 may be placed over the electroluminescent laminate 122 and the other may be placed under the electroluminescent laminate 122 to sandwich the electroluminescent laminate 122 between the anode 134 and the cathode 136.

### (4) Optical Adjustment Film

The plurality of optical adjustment films is each provided to cover the electroluminescent laminate 122, the anode 134, and the cathode 136. The optical adjustment film closest to the substrate 102 among the plurality of optical adjustment films is provided to be in contact with the electroluminescent laminate 122 and may be in contact with the anode 134 and/or the cathode 136. The number of optical adjustment films is arbitrarily determined and is two or more. The plurality of optical adjustment films each has a relatively high refractive index (e.g., from 2.0 to 2.4) and has a lower refractive index than those of the functional layers included in the electroluminescent laminate 122 (approximately 2.6). Furthermore, the plurality of optical adjustment films is preferably configured such that the refractive indices decrease with increasing distance from the electroluminescent laminate 122. The material contained in each optical adjustment film may be an inorganic material or an organic material. Examples of an inorganic material include aluminum nitride, silicon nitride, silicon oxide, titanium oxide, zirconium oxide, chromium oxide, aluminum oxide, indium oxide, lead sulfide, and the like. A polymer containing sulfur, halogen, or phosphorus is exemplified as an organic material. As a polymer containing sulfur, a polymer having a substituent such as a thioethers, a sulfone, and a thiophene in a main chain or a side chain is represented. A polymer containing phosphorus includes a polymer containing a phosphite group, a phosphate group, or the like in a main chain or a side chain and a polyphosphazene. A halogen-containing polymer includes polymers having bromine, iodine, or chlorine as a substituent. The aforementioned polymers may be intermolecularly or intramolecularly cross-linked.

More specifically, when the LED 120 has two optical adjustment films (first optical adjustment film 140 and second optical adjustment film 142), the refractive index of the first optical adjustment film 140 closest to the electroluminescent laminate 122 is higher than the refractive index of the second optical adjustment film 142 and is lower than those of the functional layers in the electroluminescent laminate 122. Thus, the refractive index of the first optical adjustment film 140 may be equal to or higher than 2.1 and equal to or lower than 2.5, and the refractive index of the second optical adjustment film 142 may be equal to or higher than 2.0 and equal to or lower than 2.2, for example. This numerical range can be satisfied by configuring the LED 120 so that the first optical adjustment film 140 contains aluminum nitride and the second optical adjustment film 142 contains silicon nitride, for example.

When the plurality of optical adjustment films includes three optical adjustment films (first optical adjustment film 140, second optical adjustment film 142, and third optical adjustment film 144) (see FIG. 2B), it is preferable to configure the LED 120 so that the refractive index decreases in the order of the first optical adjustment film 140, the second optical adjustment film 142, and the third optical adjustment film 144. Thus, the refractive index of the first optical adjustment film 140 may be equal to or higher than 2.1 and equal to or lower than 2.5, the refractive index of the second optical adjustment film 142 may be equal to or higher than 2.0 and equal to or lower than 2.2, and the refractive index of the third optical adjustment film 144 may be equal to or higher than 1.8 and equal to or lower than 2.1, for example. This numerical range can be satisfied by configuring the LED 120 so that the first optical adjustment film 140 contains aluminum nitride, the second optical adjustment film 142 contains silicon oxide, and the third optical adjustment film 144 contains silicon nitride, for example. However, the refractive index relationship is not restricted to the aforementioned relationship, and the refractive indices may increase in the order of the first optical adjustment film 140, the third optical adjustment film 144, and the second optical adjustment film 142, for example.

The optical adjustment films may be continuous between adjacent LEDs 120 (FIG. 2A and FIG. 2B) or may be divided between adjacent LEDs 120 as shown in FIG. 2C. In the former case, each optical adjustment film covers all of the LEDs 120 of the display device 100. In the latter case, a plurality of stacked optical adjustment films is arranged in an island shape.

### (5) Protective Film

As an optional component, the LED 120 may have a plurality of protective films over the plurality of optical adjustment films. The number of protective films is not restricted and may be two, three, or more. For example, as shown in FIG. 2A through FIG. 2C, the LED 120 may have two protective films (a first protective film 150 and a second protective film 152). Materials contained in each protective film include the aforementioned polymers containing sulfur, halogen, or phosphorus in addition to a silicon-containing inorganic compound such as silicon nitride, silicon oxide, silicon oxynitride, and silicon nitride oxide and a polymer such as an acrylic resin, an epoxy resin, a polyimide, and a polyamide.

The refractive relationship between the protective films and the optical adjustment films may be arbitrarily set. In a preferred embodiment, the refractive index of the first protective film 150 in contact with the uppermost optical adjustment film (e.g., the second optical adjustment film 142 or the third optical adjustment film 144) is relatively high (e.g., equal to or higher than 1.6 and equal to or lower than 2) but lower than that of the uppermost optical adjustment film, and the difference from the refractive index of the uppermost optical adjustment film is equal to or more than 0.1 and equal to or less than 0.5. It is also one of the preferred embodiments that the lowermost first protective film 150 contains a polymer. For example, the LED 120 is configured so that the first protective film 150 contains a polymer such as a polyimide while the second protective film 152 over the first protective film 150 contains a silicon-containing inorganic compound such as silicon nitride. The use of the first protective film 150 containing a polymer allows the unevenness caused by the electroluminescent laminate 122 to be absorbed, resulting in a flat top surface. Accordingly, the flatness of other protective films (e.g., the second protective film 152) formed thereover can be improved, thereby preventing the formation of pinholes and cracks caused by the unevenness.

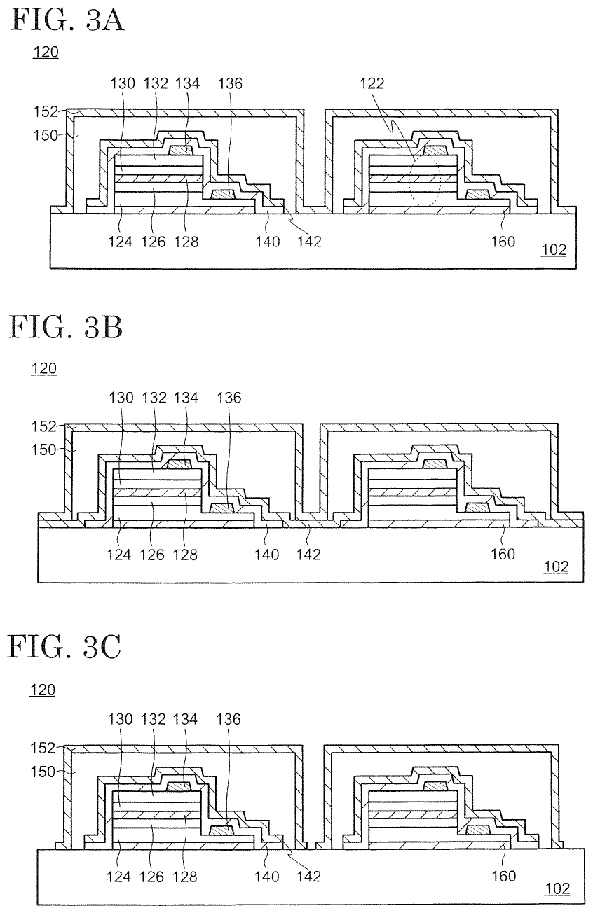

As shown in FIG. 2A through FIG. 2C, the plurality of protective films may be provided continuously over adjacent LEDs 120. When the plurality of optical adjustment films is divided between adjacent LEDs 120, a portion of the protective film (the first protective film 150 in the example shown in FIG. 2C) directly contacts with the substrate 102 or an undercoat disposed over the substrate 102. Alternatively, all or part of the plurality of protective films may be divided between adjacent LEDs 120. For example, the first protective film 150 may be divided between adjacent LEDs 120 while the second protective film 152 may be continuous over the adjacent LEDs 120 as shown in FIG. 3A. In this case, the second protective film 152 may be in contact with the substrate 102 or the undercoat, or both the second optical adjustment film 142 and the first protective film 150 may not be divided between adjacent LEDs 120 so as to be continuous over the plurality of LEDs 120 as shown in FIG. 3B. In the structure demonstrated in FIG. 3B, the first protective film 150 is sealed by the second optical adjustment film 142 and the first protective film 150. Alternatively, both the first protective film 150 and the second protective film 152 may be divided between the adjacent LEDs 120 to allow a portion of the substrate 102 or the undercoat to be exposed from the plurality of protective films as shown in FIG. 3C.

### (6) Buffer Layer

Furthermore, a buffer layer 160 may be provided as an optional configuration between the substrate 102 (or the undercoat) and the electroluminescent laminate 122 to promote crystallization of the functional layers in the electroluminescent laminate 122. The buffer layer 160 may include an insulating material or a conductive material having a hexagonal close-packed structure, a face-centered cubic structure, or a structure close to these structures. Here, the structure close to the hexagonal close-packed structure or the face-centered cubic structure includes a crystal structure in which the c-axis is not orthogonal to the a-axis and b-axis. Therefore, in this structure, the buffer layer 160 is oriented in the (0001) direction with respect to the substrate 102, namely, the c-axis direction. In addition, the buffer layer 160 having the face-centered cubic structure or the structure close thereto is oriented in the (111) direction with respect to the substrate 102. Therefore, the c-axis of the buffer layer 160 is oriented in a direction perpendicular or substantially perpendicular to the surface over which the buffer layer 160 is provided (the surface of the substrate 102 in the examples shown in FIG. 2A and FIG. 2B). On the other hand, it has been known that gallium nitride-based materials contained in the functional layers of the electroluminescent laminate 122 exist in the hexagonal close-packed structure and undergo crystal growth in the c-axis direction to minimize their surface energy. Therefore, the formation of the electroluminescent laminate 122 over the buffer layer 160 promotes the crystal growth of the functional layers in the c-axis direction. As a result, the crystallinity of the functional layers included in the electroluminescent laminate 122 is improved.

The buffer layer 160 described above may contain a metal nitride such as aluminum nitride, aluminum oxide, and titanium nitride, a metal oxide such as zinc oxide, lithium niobate (LiNbO), BiLaTiO, SrFeO, BiFeO, BaFeO, ZnFeO, and PMnN-PZT, or basic calcium phosphate (bio-apatite). The use of such materials enables the formation of an insulating buffer layer 160. Alternatively, the buffer layer 160 may contain a metal such as titanium, aluminum, silver, nickel, copper, strontium, rhodium, palladium, iridium, platinum, and gold. When a metal is included, the buffer layer 160 may be disposed under the electron-injection layer 124 and used as the cathode 136, because the buffer layer 160 is conductive and is capable of functioning as an electrode.

The buffer layer 160 may be formed using a CVD method or a sputtering method. It is preferable that the surface of the buffer layer 160 be highly flat in order to allow the functional layers to undergo crystal growth in the c-axis direction more effectively. Specifically, the arithmetic mean roughness (Ra) of the surface of the buffer layer 160 is preferred to be smaller than 2.3 nm. The root mean square roughness (Rq) of the surface of the buffer layer 160 is preferred to be smaller than 2.9 nm. The thickness of the buffer layer 160 is preferred to be equal to or less than 50 nm to obtain high surface flatness, and the buffer layer 160 is formed with a thickness equal to or more than 10 nm and equal to or less than 50 nm, for example.

As described above, the LED 120 according to the present embodiment has the plurality of optical adjustment films over the electroluminescent laminate 122. The plurality of optical adjustment films has a refractive index lower than the functional layers constituting the electroluminescent laminate 122 and is configured so that the refractive indices decrease with increasing distance from the electroluminescent laminate 122. Therefore, the refractive index difference between the electroluminescent laminate 122 and the optical adjustment film (first optical adjustment film 140) in contact therewith and between adjacent optical adjustment films can be reduced. As a result, the loss of light due to reflection at the interfaces of these films is suppressed, and the light emitted from the emission layer 128 can be efficiently extracted. Due to these effects, the implementation of an embodiment according to the present invention enables the production of a highly efficient light-emitting element, which contributes to reducing the power consumption of the display device including the light-emitting element. In addition, when the refractive index of the first protective film 150 in contact with the uppermost optical adjustment film (e.g., the second optical adjustment film 142 or the third optical adjustment film 144) is set to be lower than that of the uppermost optical adjustment film and the difference therebetween is set to be small (e.g., equal to or more than 0.1 and equal to or less than 0.5), the reflection at the interface between these films can also be suppressed. Thus, power consumption can be further reduced.

Furthermore, the formation of the plurality of protective films over the optical adjustment films prevents impurities such as water, oxygen, and metal ions from entering from the outside, thereby providing the LED 120 with high reliability. Therefore, the use of the LED 120 according to this embodiment also enables the production of a highly efficient display device with high reliability.

Since the LED 120 can be formed using a sputtering method as described above, the manufacturing process of the display device 100 does not require temperatures exceeding the strain point of amorphous glass. Therefore, it is possible to use an amorphous substrate as the substrate 102, which allows the production of not only small-sized display devices but also large-sized display devices by implementing the present embodiment.

### Second Embodiment

In the present embodiment, modified examples of the LED 120 described in the First Embodiment are explained. An explanation of the structures the same as or similar to those described in the First Embodiment may be omitted.

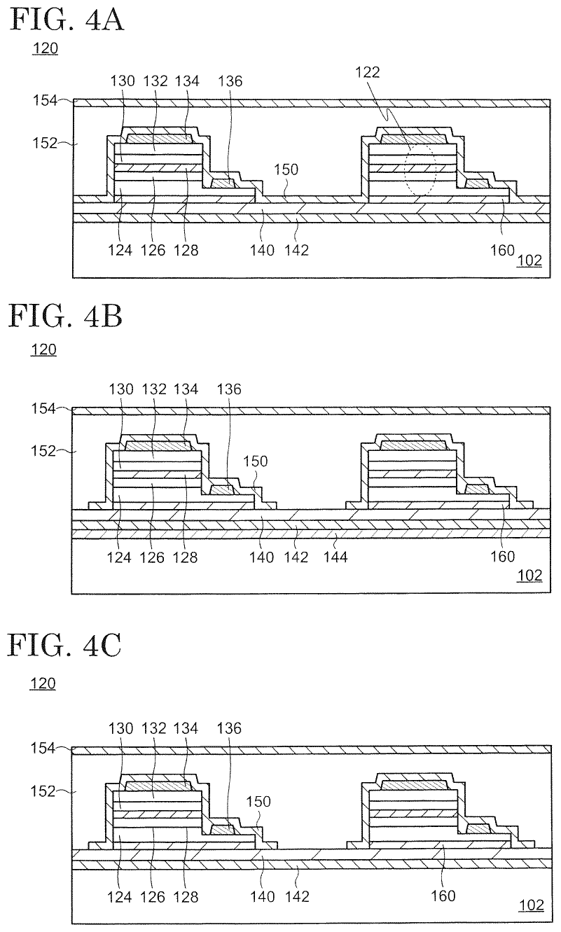

In the LED 120 according to the present modified example, the light emission from the emission layer 128 is extracted through the substrate 102. Therefore, the anode 134 which is an electrode overlapping the emission layer 128 may cover most or all of the top surface of the uppermost layer of the electroluminescent laminate 122. For example, the anode 134 may cover 70% or more, 80% or more, or 90% or more of the uppermost functional layer (e.g., the hole-injection layer 132 or the hole-transporting layer 130) of the electroluminescent laminate 122 as shown in FIG. 4A. Additionally, the plurality of optical adjustment films is provided between the substrate 102 and the electroluminescent laminate 122. That is, as can be understood from FIG. 4A, the plurality of optical adjustment films is provided over the substrate 102 directly or through an undercoat which is not illustrated, over which the electroluminescent laminate 122 is formed.

In this modified example, the plurality of optical adjustment films is also configured such that their refractive indices decrease with increasing distance from the electroluminescent laminate 122. For example, when the plurality of optical adjustment films is structured by the first optical adjustment film 140 and the second optical adjustment film 142 thereunder, the LED 120 may be configured so that the refractive index of the first optical adjustment film 140 is lower than the refractive indices of the functional layers of the electroluminescent laminate 122, and the refractive index of the second optical adjustment film 142 is lower than the first optical adjustment film 140. The materials usable in the plurality of optical adjustment films include those described in the First Embodiment, and the LED 120 may be configured such that the first optical adjustment film 140 and the second optical adjustment film 142 respectively include aluminum nitride and silicon nitride, for example. When the optical adjustment film is composed of the first optical adjustment film 140, the second optical adjustment film 142 thereunder, and the third optical adjustment film 144 under the second optical adjustment film 142 (FIG. 4B), the LED 120 may be configured so that the first optical adjustment film 140, the second optical adjustment film 142, and the third optical adjustment film 144 respectively contain aluminum nitride, silicon nitride, and silicon oxide.

When the buffer layer 160 is used, the buffer layer 160 may be provided between the plurality of optical adjustment films and the electroluminescent laminate 122. Since the light is extracted through the substrate 102, it is preferable to configure the buffer layer 160 with a material transmitting visible light. For example, it is preferable to use a metal oxide such as aluminum oxide and zinc oxide. Alternatively, the buffer layer 160 may be formed using a material having low transmittance to visible light at a thickness (e.g., equal to or more than 5 nm and equal to or less than 20 nm) allowing visible light to pass therethrough.

In this modified example, the plurality of protective films may be provided to cover the electroluminescent laminate 122. For example, the first protective film 150 and the third protective film 154 each containing a silicon-containing inorganic compound and the second protective film 152 containing a polymer and sandwiched between the first protective film 150 and the third protective film 154 may be provided over the electroluminescent laminate 122 as shown in FIG. 4A. In such a structure, it is possible to prevent the contact of the polymer which readily captures water and oxygen with the electroluminescent laminate 122, thereby effectively suppressing the entrance of impurities into the electroluminescent laminate 122.

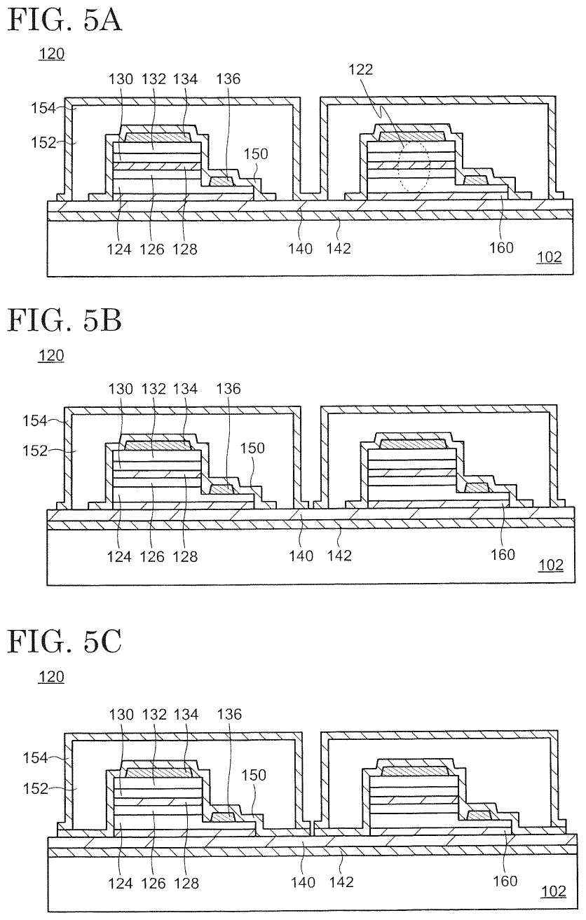

Similar to the First Embodiment, all of the plurality of protective films may be continuous between adjacent LEDs 120 (FIG. 4A), or a part of or all of the plurality of protective films may be divided. For example, the first protective film 150 may be divided between adjacent LEDs 120, while the other protective films (second protective film 152 and third protective film 154) may be continuous between adjacent LEDs 120 as shown in FIG. 4B. In this case, the first protective films 150 are formed as an island shape, and the second protective film 152 contacts the first optical adjustment film 140. Alternatively, the first protective film 150 and the second protective film 152 may be divided between adjacent LEDs 120, while the other protective film (the third protective film 154) may be continuous between adjacent LEDs 120 as shown in FIG. 5A. In this case, the second protective film 152 and the third protective film 154 contact the first optical adjustment film 140. Alternatively, all of the plurality of protective films may be divided between adjacent LEDs 120 as shown in FIG. 5B and FIG. 5C. In this case, the third protective film 154 may be in contact with the first optical adjustment film 140 or the first protective film 150.

In this modified example, the plurality of optical adjustment films suppresses the light loss caused by the reflection at the interface between the electroluminescent laminate 122 and the optical adjustment film in contact with the electroluminescent laminate 122 and the reflection at the interface between adjacent optical adjustment films so that the light emitted from the emission layer 128 can be efficiently extracted, similar to the LED 120 described in the First Embodiment. Therefore, implementation of an embodiment according to the present invention enables the production of a highly efficient light-emitting element, which contributes to a reduction of power consumption of the display devices including the light-emitting element.

### Third Embodiment

In this embodiment, a lighting device including the LED 120 described in the First or Second Embodiment is explained. An explanation of the structures the same as or similar to those described in the First or Second Embodiment may be omitted.

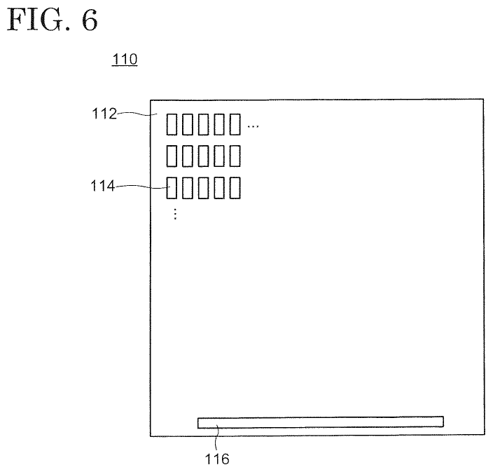

The LED 120 described in the First and Second Embodiments can be used not only for display devices but also for lighting devices. A schematic top view of a lighting device 110 according to this embodiment of the present invention is shown in FIG. 6. As shown in FIG. 6, the lighting device 110 has a substrate 112 and one or a plurality of light sources 114 over the substrate 112. The arrangement of the plurality of light sources 114 is arbitrarily determined, and the plurality of light sources 114 may be arranged in a matrix shape as shown in FIG. 6 or on concentric circles although not illustrated. Alternatively, the plurality of light sources 114 may be randomly arranged. The shape of the substrate 112 is also arbitrarily selected and may be determined as appropriate in view of the location where the lighting device 110 is installed as well as the design of the lighting device 110. For example, the planar shape of the substrate 112 may be circular, oval, or regular polygonal.

A driver circuit 116 connected to each light source 114 is provided over the substrate 112 and is electrically connected to the light source 114 by a wiring which is not illustrated. The driver circuit 116 is configured to receive control instructions from a control device, which is not illustrated, either via a wiring or wirelessly and to control the light sources 114 according to the control instructions.

The LED 120 described in the First or Second Embodiment is arranged in each light source 114. As described above, the LED 120 is provided with the plurality of optical adjustment films so that the LED 120 has high emission efficiency. It is also possible to provide a plurality of protective films. Therefore, the LED 120 is capable of emitting light with high luminance and is highly reliable. Therefore, implementation of this embodiment enables the production of lighting devices exhibiting low power consumption and high reliability.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A light-emitting element comprising:
a substrate;
an electroluminescent laminate located over the substrate and including a plurality of functional layers containing a gallium nitride-based material;
an anode and a cathode electrically connected to the electroluminescent laminate; and
a plurality of optical adjustment films over the electroluminescent laminate,
wherein the plurality of optical adjustment films is configured so that refractive indices decrease with increasing distance from the electroluminescent laminate.

2. The light-emitting element according to claim 1,
wherein the plurality of optical adjustment films independently contains a material selected from aluminum nitride, silicon nitride, silicon oxide, titanium oxide, zirconium oxide, chromium oxide, aluminum oxide, indium oxide, lead sulfide, and a polymer containing sulfur, halogen, or phosphorus.

3. The light-emitting element according to claim 1,
wherein the plurality of optical adjustment films includes a first optical adjustment film and a second optical adjustment film over the first optical adjustment film, and
the first optical adjustment film and the second optical adjustment film respectively contain aluminum nitride and silicon nitride.

4. The light-emitting element according to claim 1, further comprising a plurality of protective films over the electroluminescent laminate, the anode, and the cathode,
wherein the plurality of protective films independently contains a material selected from silicon nitride, silicon oxide, an acrylic resin, an epoxy resin, and a polyimide.

5. The light-emitting element according to claim 4,
wherein the plurality of protective films comprises a first protective film and a second protective film over the first protective film,
the first protective film contains a material selected from an acrylic resin, an epoxy resin, and a polyimide, and
the second protective film contains a material selected from silicon nitride and silicon oxide.

6. The light-emitting element according to claim 1, further comprising a buffer layer between the substrate and the electroluminescent laminate, the buffer layer orienting in a (0001) direction or a (111) direction with respect to the substrate.

7. The light-emitting element according to claim 1,
wherein the substrate contains glass.

8. A display device comprising the light-emitting element according to claim 1.

9. A lighting device comprising the light-emitting element according to claim 1.

10. A light-emitting element comprising:
a substrate;
a plurality of optical adjustment films over the substrate;
an electroluminescent laminate located over the plurality of optical adjustment films and including a plurality of functional layers containing a gallium nitride-based material; and
an anode and a cathode electrically connected to the electroluminescent laminate,
wherein the plurality of optical adjustment films is configured so that refractive indices decrease with increasing distance from the electroluminescent laminate.

11. The light-emitting element according to claim 10,
wherein the plurality of optical adjustment films independently contains a material selected from aluminum nitride, silicon nitride, silicon oxide, titanium oxide, zirconium oxide, chromium oxide, aluminum oxide, indium oxide, lead sulfide, and a polymer containing sulfur, halogen, or phosphorus.

12. The light-emitting element according to claim 10,
wherein the plurality of optical adjustment films includes a first optical adjustment film and a second optical adjustment film under the first optical adjustment film, and
the first optical adjustment film and the second optical adjustment film respectively contain aluminum nitride and silicon nitride.

13. The light-emitting element according to claim 10, further comprising a plurality of protective films over the electroluminescent laminate, the anode, and the cathode,
wherein the plurality of protective films independently contains a material selected from silicon nitride, silicon oxide, an acrylic resin, an epoxy resin, and a polyimide.

14. The light-emitting element according to claim 13,
wherein the plurality of protective films comprises a first protective film and a second protective film over the first protective film,
the first protective film contains a material selected from an acrylic resin, an epoxy resin, and a polyimide, and
the second protective film contains a material selected from silicon nitride and silicon oxide.

15. The light-emitting element according to claim 10, further comprising a buffer layer between the plurality of optical adjustment films and the electroluminescent laminate, the buffer layer orienting in a (0001) direction or a (111) direction with respect to the substrate.

16. The light-emitting element according to claim 10,
wherein the substrate contains glass.

17. A display device comprising the light-emitting element according to claim 10.

18. A lighting device comprising the light-emitting element according to claim 10.
